(19) United States
(12) Patent Application Publication
(10) Pub. No.: US 2025/0226267 A1
(43) Pub. Date: Jul. 10, 2025

(54) METHOD OF CORRECTING ERROR OF WAFER-LIKE SENSING APPARATUS

(71) Applicant: Samsung Electronics Co., Ltd., Suwon-si (KR)

(72) Inventor: Jonghwa Kim, Suwon-si (KR)

(21) Appl. No.: 19/003,216

(22) Filed: Dec. 27, 2024

(30) Foreign Application Priority Data
Jan. 4, 2024 (KR) 10-2024-0001733

(51) Int. Cl. H01L 21/66; H01L 21/67

(52) U.S. Cl. CPC H01L 22/20; H01L 21/67253

(57) ABSTRACT

A method of correcting an error of a wafer-like sensing apparatus includes repeatedly sensing a physical quantity at a same measurement point by rotating a wafer-like sensing apparatus having a plurality of sensors arranged along a virtual circumference, calculating a representative value from a plurality of measurement values extracted through the repeated sensing and calculating a unique error of each of the plurality of sensors by using the representative value, and correcting an error of the wafer-like sensing apparatus by using the unique error of each of the plurality of sensors.

### CROSS-REFERENCE TO RELATED APPLICATION

This application is based on and claims priority under 35 U.S.C. § 119 to Korean Patent Application No. 10-2024-0001733, filed on Jan. 4, 2024, in the Korean Intellectual Property Office, the disclosure of which is incorporated by reference herein in its entirety.

### BACKGROUND

Embodiments of the inventive concept relate to a method of correcting a sensing apparatus that enables a measurement environment to be accurately sensed.

Various semiconductor processes, such as etching, ashing, ion implantation, thin film deposition, and cleaning may be performed to manufacture semiconductor devices. Various types of sensing apparatuses are used to measure various parameters for a state or the like of processing equipment used in semiconductor processes. It may be difficult to continuously measure and evaluate process states within processing equipment through such sensing apparatuses to maintain the process states at desired levels.

### SUMMARY

The inventive concept provides a method of correcting an error of a wafer-like sensing apparatus that enables improved accuracy in the sensing of various parameters needed to be measured during a semiconductor process.

In addition, problems to be solved according to embodiments of the inventive concept are not limited to the above-mentioned problems, and other problems may be clearly understood by one of ordinary skill in the art from the following description.

According to an aspect of the inventive concept, there is provided a method of correcting an error of a wafer-like sensing apparatus including repeatedly sensing a physical quantity at a same measurement point by rotating a wafer-like sensing apparatus having a plurality of sensors arranged along a virtual circumference, calculating a representative value from a plurality of measurement values extracted through the repeated sensing and calculating a unique error of each of the plurality of sensors by using the representative value, and correcting an error of the wafer-like sensing apparatus by using the unique error of each of the plurality of sensors.

According to another aspect of the inventive concept, there is provided a method of correcting an error of a wafer-like sensing apparatus including calibrating a plurality of sensors included in the wafer-like sensing apparatus, repeatedly sensing a physical quantity at a same measurement point by using n sensors from among the plurality of sensors by rotating the wafer-like sensing apparatus clockwise or counterclockwise incrementally with each increment corresponding to a first angle, and calculating a calibration error of each of the n sensors by using a plurality of measurement values of the n sensors extracted through the repeated sensing, where n is a natural number of 2 or more.

According to another aspect of the inventive concept, there is provided a method of correcting an error of a wafer-like sensing apparatus including the wafer-like sensing apparatus, which includes a substrate and a plurality of sensors arranged such that adjacent ones of the plurality of sensors are spaced apart at a first angle along a virtual circumference having a center of the substrate as a center point, rotating at increments corresponding to the first angle to repeatedly sense temperature, humidity, a distribution of plasma, a density of the plasma, a magnetic field, or static electricity at a same measurement point, by a measurement value extraction module, extracting a plurality of measurement values measured respectively by the plurality of sensors through the repeated sensing, by an error calculation module, receiving the plurality of measurement values from the measurement value extraction module and calculating unique errors of the plurality of sensors, and by a correction module, correcting the error of the wafer-like sensing device by using the unique errors of the plurality of sensors.

### BRIEF DESCRIPTION OF THE DRAWINGS

Embodiments will be more clearly understood from the following detailed description taken in conjunction with the accompanying drawings in which:

FIG. 1 is an example plan view of a wafer-like sensing apparatus used in a method of correcting an error of a wafer-like sensing apparatus, according to an embodiment;

FIG. 2 is a flowchart schematically illustrating a method of correcting an error of a wafer-like sensing apparatus, according to an embodiment;

FIG. 3 is a view illustrating calibration of a plurality of sensors, which is included in a method of correcting an error of a wafer-like sensing apparatus, according to an embodiment;

FIGS. 4A to 4H are plan views of a wafer-like sensing apparatus illustrating a method of correcting an error of a wafer-like sensing apparatus, according to an embodiment;

FIG. 5 is a plan view of a wafer-like sensing apparatus illustrating a method of correcting an error of a wafer-like sensing apparatus, according to an embodiment;

FIG. 6 is a graph obtained through a repeatedly sensing operation included in a method of correcting an error of a wafer-like sensing apparatus, according to an embodiment;

FIG. 7 is a plan view illustrating a schematic arrangement structure of a wafer-like sensing apparatus and a heater used in a method of correcting an error of a wafer-like sensing apparatus, according to an embodiment; and

FIG. 8 is a flowchart illustrating an error correction system for performing a method of correcting an error of a wafer-like sensing apparatus, according to an embodiment.

### DETAILED DESCRIPTION OF THE EMBODIMENTS

Hereinafter, embodiments will be described in detail with reference to the accompanying drawings. The same reference numerals are used for the same components in the drawings, and the descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

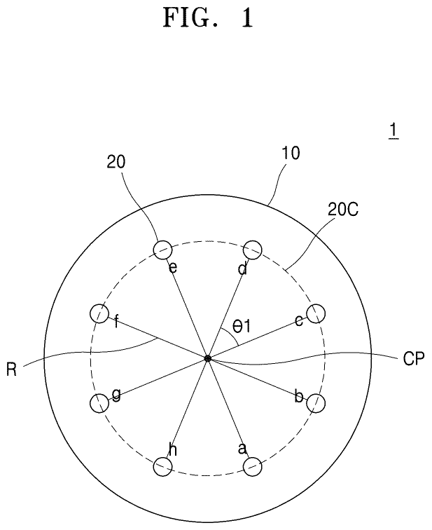

FIG. 1 is an example plan view of a wafer-like sensing apparatus used in a method of correcting an error of a wafer-like sensing apparatus, according to an embodiment. Referring to FIG. 1, a wafer-like sensing apparatus 1 may include a substrate 10 and a plurality of sensors 20.

The substrate 10 may have a wafer shape. The substrate 10 may be formed to have a size and shape corresponding to a wafer. For example, the substrate 10 may have a circular plate shape like a wafer. In an embodiment, the substrate 10 may be moved and handled within equipment in the same manner as an actual wafer processed through equipment of a semiconductor manufacturing process. Accordingly, the wafer-like sensing apparatus 1 including the substrate 10 may sense a physical quantity of various process conditions instead of sensing the conditions of an actual semiconductor wafer.

The plurality of sensors 20 may be mounted on the substrate 10. The plurality of sensors 20 may be components for collecting data regarding an environment in which the substrate 10 is located. The plurality of sensors 20 may sense various physical quantities, such as, but not limited to, temperature, humidity, a distribution of plasma, a density of plasma, a magnetic field, and static electricity. For example, the plurality of sensors 20 may sense a temperature at which the plurality of sensors 20 are heated by a heater adjacent thereto.

The plurality of sensors 20 may be arranged along a virtual circumference 20C on a plane. The plurality of sensors 20 may be arranged along a circular edge having a center of the substrate 10 as a center point CP. In other words, the plurality of sensors 20 may be located at the same radius R from the center of the substrate 10.

The plurality of sensors 20 may be arranged at equal intervals along the virtual circumference 20C. Referring to the example of FIG. 1, the plurality of sensors 20 my include a sensor a, a sensor b, a sensor c, a sensor d, a sensor e, a sensor f, a sensor g, and a sensor h, and the sensor a, the sensor b, the sensor c, the sensor d, the sensor e, the sensor f, the sensor g, and the sensor h may be located spaced apart from one another at every first angle θ1. In the example of FIG. 1, the plurality of sensors 20 include eight sensors, and thus, the first angle θ1 may be 45°.

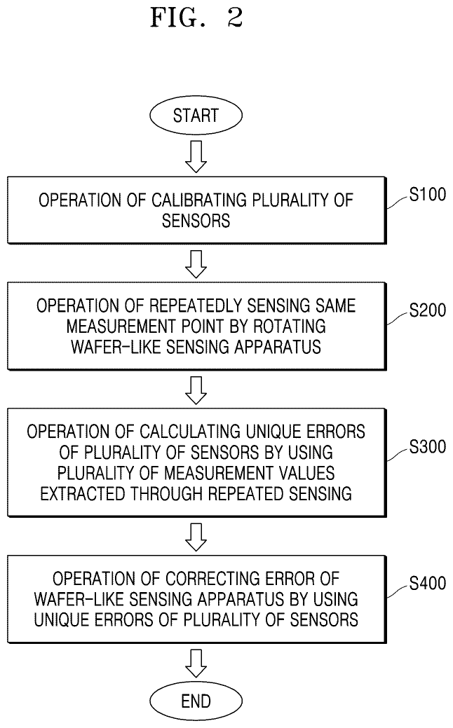

FIG. 2 is a flowchart schematically illustrating a method of correcting an error of a wafer-like sensing apparatus, according to an embodiment.

Referring to FIG. 2, the method of correcting the error of the wafer-like sensing apparatus, according to an embodiment, may include operation S100 of calibrating the plurality of sensors 20 (refer to FIG. 1), operation S200 of repeatedly sensing the same physical quantity at the same measurement point by rotating the wafer-like sensing apparatus, operation S300 of calculating unique errors of one or more of the plurality of sensors 20 (refer to FIG. 1) by using a plurality of measurement values extracted through the repeated sensing of operation S200, and operation S400 of correcting an error of the wafer-like sensing apparatus by using the unique errors of one or more of the plurality of sensors 20 (refer to FIG. 1).

The plurality of sensors 20 (refer to FIG. 1) may be calibrated (corrected). The calibration may indicate that a value of a measuring apparatus is compared with a standard and corrected. Operation S100 of calibrating the plurality of sensors 20 (refer to FIG. 1) may be performed by immersing the wafer-like sensing apparatus 1 including the plurality of sensors 20 (refer to FIG. 1) in a liquid.

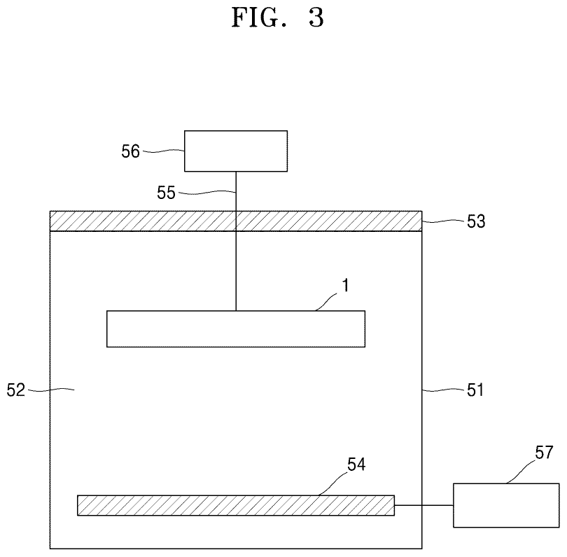

FIG. 3 is a view illustrating calibration of a plurality of sensors. Referring to FIG. 3, a calibration system may include a container 51, a liquid 52, a cover 53, a heating/cooling unit 54, a connection line 55, an electric device 56, and a temperature controller 57. The container 51 may contain the liquid 52, and the cover 53 may cover an upper end of the container 51. The liquid 52 may be any liquid that provides an environment of uniform temperature to a wafer-like sensing apparatus 1. The heating/cooling unit 54 may be a heating/cooling apparatus such as an electric heater or a cooler. The temperature controller 57 may be connected to the heating/cooling unit 54 to adjust the heating/cooling unit 54.

The electric device 56 may be an external controller located outside the container 51. The electric device 56 may provide power to the wafer-like sensing apparatus 1 located inside the container 51 through the connection line 55. In addition, the electric device 56 may be electrically connected to the temperature controller 57 through an electric line (not shown). The connection line 55 may electrically connect the electric device 56 to the wafer-like sensing apparatus 1. Measurement signals sensed by the plurality of sensors 20 (refer to FIG. 1) of the wafer-like sensing apparatus 1 may be extracted or communicated to the outside of the container 51 through the connection line 55.

Operation S200 of FIG. 2 of calibrating the plurality of sensors 20 (refer to FIG. 1) may be carried out by immersing the plurality of sensors 20 (refer to FIG. 1) in the liquid 52 having relatively high specific heat within the container 51 to easily reach thermal equilibrium and maintain thermal equilibrium.

The wafer-like sensing apparatus 1 having a waterproofed battery, memory, and operation chip attached thereto may not represent characteristics (e.g., specific heat, heat capacity, and the like) of the wafer-like sensing apparatus 1, and thus, calibration using a liquid as described above may be performed in a state (i.e., a semi-assembled state) without attaching the battery, memory, and operation chip to the wafer-like sensing apparatus 1. As described above, the wafer-like sensing apparatus 1 located inside the container 51 may be supplied with power from the outside of the container 51 through the connection line 55. In the case of the wireless type wafer-like sensing apparatus 1, the battery, the memory, and the operation chip may be attached to the wafer-like sensing apparatus 1 after calibration, and thus, a calibration error may occur. A calibration error may occur even in the case of the wired type wafer-like sensing apparatus 1. In the repeatedly sensing operation S200, the wafer-like sensing apparatus 1 may include the battery, the memory, and the operation chip attached to a substrate.

The method of correcting the error of the wafer-like sensing apparatus 1, according to an embodiment, may calculate and use unique errors of one or more of a plurality of sensors. In an embodiment, the unique errors of one or more of the plurality of sensors may be errors of the calibration described above. In an embodiment, an operation of calibrating a plurality of sensors may be omitted, and the method of correcting the error according to an embodiment may be applied to all of the wafer-like sensing apparatuses 1 in which calibration for a plurality of sensors are performed or is not performed.

Referring back to FIG. 2, the method of correcting the error of the wafer-like sensing apparatus 1, according to an embodiment, may include operation S200 of repeatedly sensing the same physical quantity at the same measurement point by rotating the wafer-like sensing apparatus 1, operation S300 of calculating unique errors of the plurality of sensors 20 by using a plurality of measurement values extracted or received through repeated sensing, and operation S400 of correcting the error of the wafer-like sensing apparatus 1 by using the unique errors of the plurality of sensors 20.

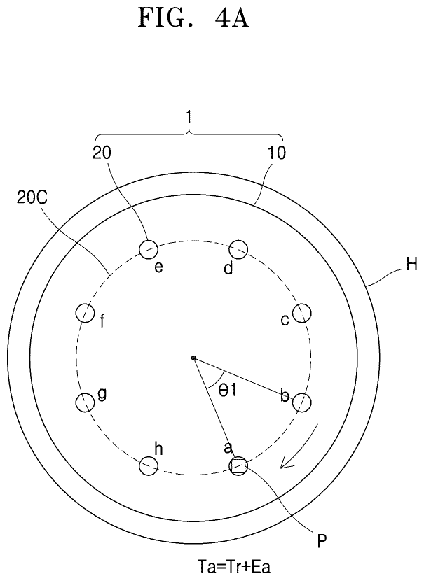

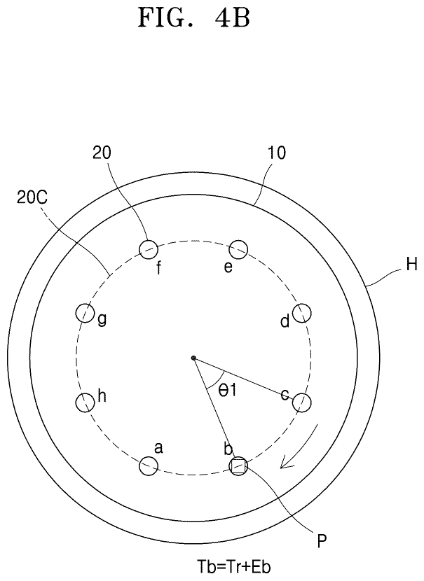

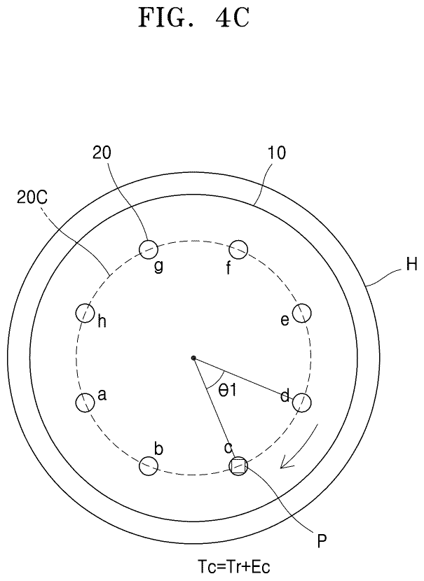

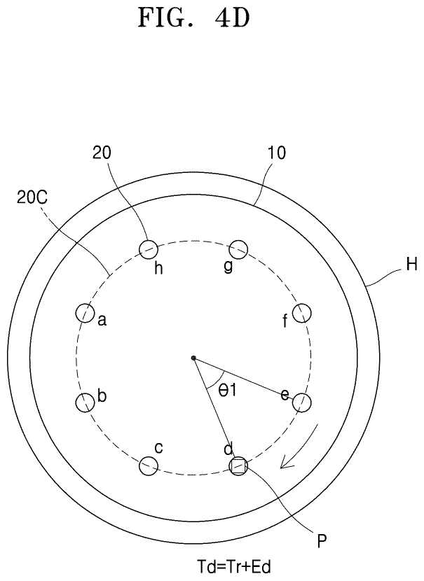

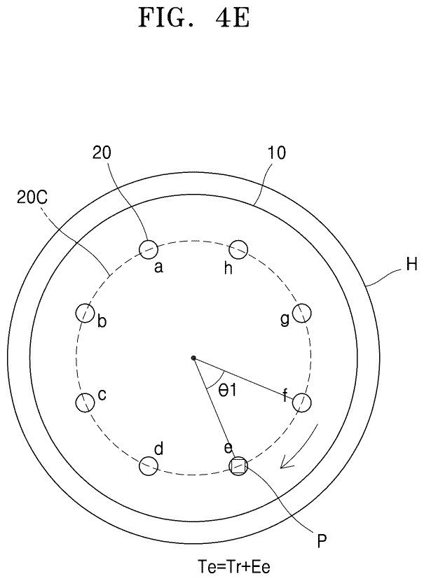

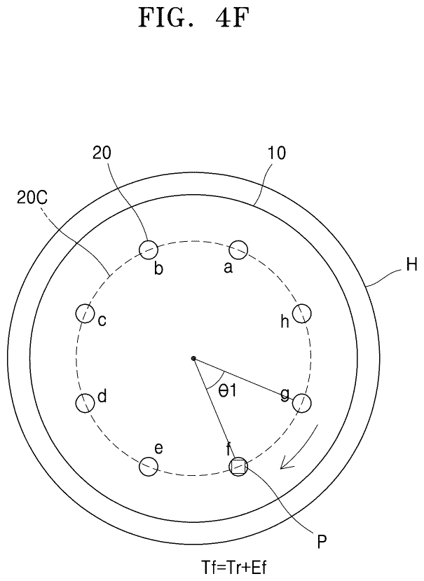

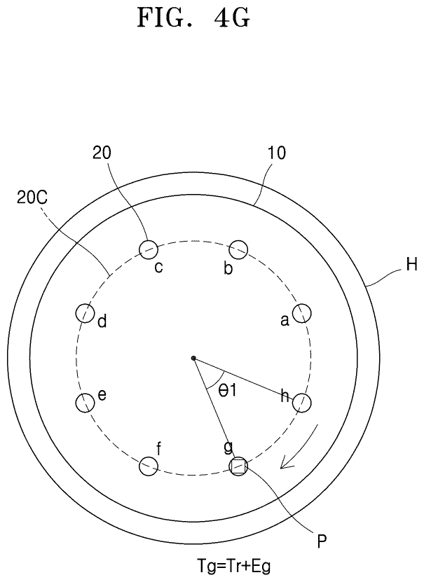

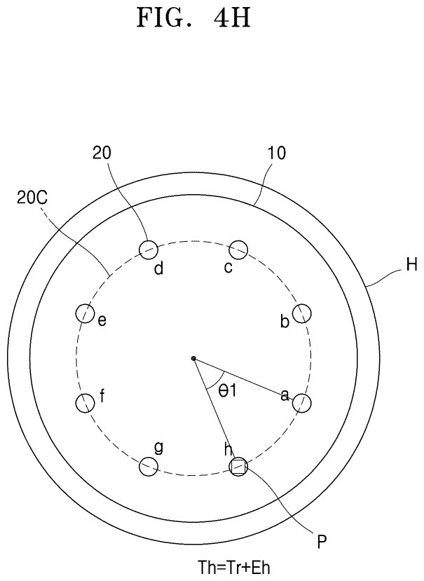

FIGS. 4A to 4H are plan views of a wafer-like sensing apparatus illustrating a method of correcting an error of a wafer-like sensing apparatus, according to an embodiment. FIGS. 4A to 4H illustrate an example in which a plurality of sensors 20 measure a temperature of a measurement point heated by a heater H adjacent thereto.

FIGS. 4A to 4H illustrate operation S200 of repeatedly sensing by using the wafer-like sensing apparatus 1 illustrated in FIG. 1.

Referring to FIGS. 4A to 4H, as described above with reference to FIG. 1, the plurality of sensors 20 may include a sensor a, a sensor b, a sensor c, a sensor d, a sensor e, a sensor f, a sensor g, and a sensor h. The sensor a, the sensor b, the sensor c, the sensor d, the sensor e, the sensor f, the sensor g, and the sensor h may be spaced apart from one another at every first angle θ1 and arranged at equal intervals, on a virtual circumference 20C. In operation S200 of repeatedly sensing by rotating the wafer-like sensing apparatus 1, the wafer-like sensing apparatus 1 may rotate at every first angle θ1, which is a spacing interval between the plurality of sensors 20, to repeatedly sense the temperature at the same measurement point P. The wafer-like sensing apparatus 1 may rotate clockwise or counterclockwise.

FIG. 4A illustrates an arrangement in which the sensor a senses the temperature at the measurement point P. Comparing FIG. 4B to FIG. 4A, FIG. 4B illustrates an arrangement in which the wafer-like sensing apparatus 1 of FIG. 4A rotates clockwise at the first angle θ1 and thus the sensor b senses the temperature at the measurement point P. Similarly, FIG. 4C illustrates an arrangement in which the wafer-like sensing apparatus 1 of FIG. 4B rotates clockwise at the first angle θ1 and thus the sensor c senses the temperature at the measurement point P. FIG. 4D illustrates an arrangement in which the wafer-like sensing apparatus 1 of FIG. 4C rotates clockwise at the first angle θ1 and thus the sensor d senses the temperature at the measurement point P. FIG. 4E illustrates an arrangement in which the wafer-like sensing apparatus 1 of FIG. 4D rotates clockwise at the first angle θ1 and thus the sensor e senses the temperature at the measurement point P. FIG. 4F illustrates an arrangement in which the wafer-like sensing apparatus 1 of FIG. 4E rotates clockwise at the first angle θ1 and thus the sensor f senses the temperature at the measurement point P. FIG. 4G illustrates an arrangement in which the wafer-like sensing apparatus 1 of FIG. 4F rotates clockwise at the first angle θ1 and thus the sensor g senses the temperature at the measurement point P. FIG. 4H illustrates an arrangement in which the wafer-like sensing apparatus 1 of FIG. 4G rotates clockwise at the first angle θ1 and thus the sensor h senses the temperature at the measurement point P. Referring to FIGS. 4A to 4H, the sensor a, the sensor b, the sensor c, the sensor d, the sensor e, the sensor f, the sensor g, and the sensor h may all sense the temperature at the same measurement point P.

FIGS. 4A to 4H illustrate that the sensor a, the sensor b, the sensor c, the sensor d, the sensor e, the sensor f, the sensor g, and the sensor h are arranged spaced apart from one another at every first angle θ1, and the wafer-like sensing apparatus 1 rotates at every first angle θ1 to repeatedly to sense the temperature at the measurement point P, but the sensor arrangements and operations according to embodiments of the inventive concept are not limited thereto. For example, the sensor a, the sensor b, the sensor c, the sensor d, the sensor e, the sensor f, the sensor g, and the sensor h may be arranged at random intervals rather than at equal intervals. Here, the wafer-like sensing apparatus 1 may repeatedly sense the temperature at the measurement point P by rotating to correspond to any angle at which the sensor a, the sensor b, the sensor c, the sensor d, the sensor e, the sensor f, the sensor g, and the sensor h are spaced apart from one another.

After the repeatedly sensing operation S200, operation S300 of calculating unique errors of the plurality of sensors 20 by using a plurality of measurement values extracted or received through repeated sensing may be performed. The unique errors of the plurality of sensors 20 may be calculated by calculating a representative value from a plurality of measurement values extracted or received through repeated sensing and determining that the representative value is the same as a true value of the temperature at the measurement point P. In other words, the unique errors of one or more of the plurality of sensors 20 may be used by determining the calculated representative value as the true value of the temperature at the measurement point P. The unique errors of the plurality of sensors 20 may be calculated.

The representative value may be calculated by using, in various methods, the plurality of measurement values extracted or received through repeated sensing. In an embodiment, the representative value may be an average value of the plurality of measurement values. In an embodiment, the representative value may be an average value excluding some (e.g., a minimum value and a maximum value) of the plurality of measurement values. In an embodiment, the representative value may be calculated by considering (or using) a root mean square (RMS) of the plurality of measurement values. For example, a value at which a root mean square error (RMSE) becomes the minimum may be calculated as the representative value. Hereinafter, for brief description, the representative value may be mainly described as the average value of the plurality of measurement values.

In an embodiment, the unique errors of the plurality of sensors 20 may be calculated by determining each of a plurality of measurement values Ta, Tb, Tc, Td, Te, Tf, Tg, and Th extracted or received through repeated sensing as a value obtained by adding each of unique errors Ea, Eb, Ec, Ed, Ee, Ef, Eg, and Eh of the plurality of sensors 20a to a true value Tr of the same physical quantity at the measurement point P.

In an embodiment, the unique errors of the plurality of sensors 20 may be calculated by determining that the plurality of measurement values Ta, Tb, Tc, Td, Te, Tf, Tg, and Th extracted through repeated sensing follow a Gaussian distribution. The center of the Gaussian distribution may be determined as the true value Tr of the measurement point P. The unique errors of the plurality of sensors 20 may be calculated by determining that an average value Tm of the plurality of measurement values Ta, Tb, Tc, Td, Te, Tf, Tg, and Th extracted or received through repeated sensing is the same as the true value Tr of the measurement point P. In other words, the unique errors of the plurality of sensors 20 may be calculated by determining that the average value Tm of the plurality of measurement values Ta, Tb, Tc, Td, Te, Tf, Tg, and Th is calculated as the representative value from the plurality of measurement values Ta, Tb, Tc, Td, Te, Tf, Tg, and Th, and the representative value is the same as the true value Tr of the same physical quantity at the measurement point P.

Hereinafter, a method of calculating a unique error of the sensor a is briefly described below by using the sensor a as an example.

As in Equation 1 below, the measurement value Ta obtained by sensing the physical quantity at the measurement point P by the sensor a may be determined by adding the unique error Ea of the sensor a to the true value Tr of the physical quantity at the measurement point P.

$$Ta = Tr = Ea \qquad [ Equation 1 ]$$

When the plurality of measurement values Ta, Tb, Tc, Td, Te, Tf, Tg, and Th obtained through sensing by the sensor a, the sensor b, the sensor c, the sensor d, the sensor e, the sensor f, the sensor g, and the sensor h follow the Gaussian distribution having the true value Tr as the center, as in Equation 2, the average value Tm of the plurality of measurement values Ta, Tb, Tc, Td, Te, Tf, Tg, and Th may be determined to be the same as the true value Tr. In other words, an estimated value Trₑₛₜₘ of the true value Tr may be the average value Tm of the plurality of measurement values Ta, Tb, Tc, Td, Te, Tf, Tg, and Th. The description of the Gaussian distribution is for conceptual description, and in an embodiment, regardless of the Gaussian distribution, the average value Tm of the plurality of measurement values Ta, Tb, Tc, Td, Te, Tf, Tg, and Th obtained through sensing by the sensor a, the sensor b, the sensor c, the sensor d, the sensor e, the sensor f, the sensor g, and the sensor h may be calculated as the representative value, and the representative value may be expressed as the estimated value Trₑₛₜₘ of the true value Tr.

$$Tm = \frac{Ta + Tb + Tc + Td + Te + Tf + Tg + Th}{8} = Tr + \frac{Ea + Eb + Ec + Ed + Ee + Ef + Eg + Eh}{8} \approx Tr \qquad [ Equation 2 ]$$

$$∴ {Tr}_{estm} = Tm$$

As in Equation 3, a unique error Eaₑₛₜₘ of the sensor a may be calculated as a value obtained by subtracting the average value Tm of the plurality of measurement values Ta, Tb, Tc, Td, Te, Tf, Tg, and Th from the measurement value Ta of the sensor a. In Equation 1, Equation 2, and Equation 3, Ea may refer to a unique error of the conceptual sensor a, and Eaₑₛₜₘ may refer to a unique error of the sensor a calculated according to an embodiment.

$${Ea}_{estm} = Ta - {Tr}_{estm} = Ta - Tm \qquad [ Equation 3 ]$$

In the same method as described through Equation 1, Equation 2, and Equation 3, a unique error of each of the plurality of sensors 20 may be calculated.

After operation S300 of calculating the unique errors of the plurality of sensors 20, operation S400 of correcting the error of the wafer-like sensing apparatus 1 by using the calculated unique errors of the plurality of sensors 20 may be performed.

Operation S400 of correcting the error of the wafer-like sensing apparatus 1 may include an operation in which each of the sensors 20 senses a physical quantity (e.g., temperature, humidity, a distribution of plasma distribution, a density of plasma, a magnetic field, and/or static electricity) to obtain a result value and an operation of subtracting the unique error of each of the plurality of sensors 20 from the obtained result value. Here, the unique error of each of the plurality of sensors 20 may refer to a unique error (e.g., Eaₑₛₜₘ in Equation 3) calculated in the operation of calculating the unique errors of the plurality of sensors 20. While described herein as determining unique errors for each of the plurality of the sensors 20, it will be understood that one or more of the unique errors of the plurality of sensors 20 may be determined in according to some embodiments of the inventive concept.

Taking the sensor a as an example, the sensor a may sense a physical quantity at a measurement location corresponding thereto to obtain a result value Ta′. As in Equation 4 below, a correction result value Ta_{c}′ of the result value Ta′, which is obtained through sensing by using the sensor a, may be calculated by subtracting the pre-calculated unique error Eaₑₛₜₘ of the sensor a from the result value Ta′ obtained through sensing.

$${Ta}_{c}^{′} = {Ta}^{′} - {Ea}_{estm} \qquad [ Equation 4 ]$$

In the method as described above, a result value obtained through sensing by each of the plurality of sensors 20 or one or more of the plurality of sensors 20 may be corrected, and accordingly, the error of the wafer-like sensing apparatus 1 may be corrected.

In particular, when the number of plurality of sensors 20 increases, the error of the wafer-like sensing apparatus 1 may be more accurately corrected. In detail, taking the sensor a as an example, the calculated unique error (Eaₑₛₜₘ) of the sensor a may be expressed as in Equation 5 below (refer to Equation 1, Equation, 2, and Equation 3).

$${Ed}_{estm} = Ta - ( Tr + \frac{Ea + Eb + Ec + Ed + Ee + Ef + Eg + Eh}{8} ) = Ea - \frac{Ea + Eb + Ec + Ed + Ee + Ef + Eg + Eh}{8} \qquad [ Equation 5 ]$$

When the correction result value Ta_{c}′ of the sensor a is expressed by using Equation 5, the correction result value Ta_{c}′ of the sensor a may be expressed as in Equation 6 below.

$${Ta}_{c}^{′} = {Ta}^{′} - {Ea}_{estm} = ( Tr + Ea ) - ( Ea - \frac{Ea + Eb + Ec + Ed + Ee + Ef + Eg + Eh}{8} ) = Tr + \frac{Ea + Eb + Ec + Ed + Ee + Ef + Eg + Eh}{8} \qquad [ Equation 6 ]$$

As described above, when a plurality of result values Ta′, Tb′, Tc′, Td′, Te′, Tf, Tg′, and Th′ obtained through sensing by the plurality of sensors 20 follow the Gaussian distribution on the basis of the true value Tr, a value excluding the true value Tr from the right term of Equation 6 may approach 0 with the increase in the number of plurality of sensors 20, and thus, the correction result value Ta_{c}′ of the sensor a may have a more accurate value. In other words, when the number of plurality of sensors 20 increases, the error of the wafer-like sensing apparatus 1 may be more accurately corrected.

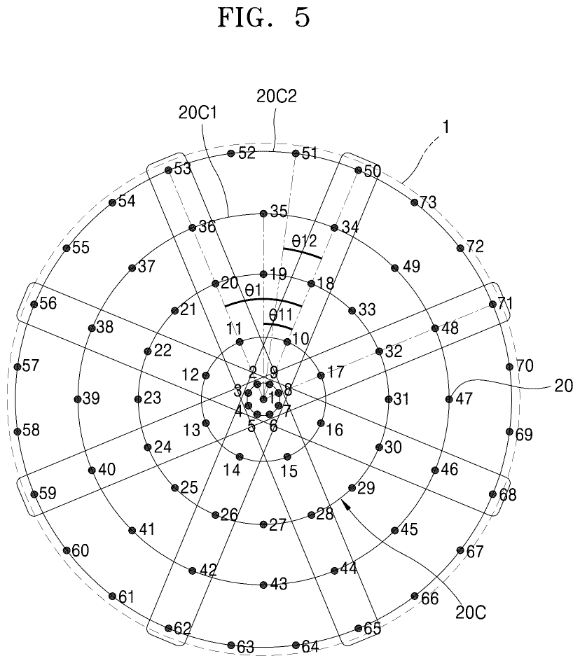

FIG. 5 is a plan view of a wafer-like sensing apparatus 1 illustrating a method of correcting an error a wafer-like sensing apparatus, according to an embodiment.

Referring to FIG. 5, a plurality of sensors 20 may be arranged along a virtual circumference 20C on a plane. A plurality of virtual circumferences 20C may be provided. In other words, the plurality of sensors 20 may be arranged in a concentric circle shape. A center point of the concentric circle may be the center of the substrate 10 (refer to FIG. 1).

In an embodiment, the virtual circumference 20C may include a first circumference and a second circumference having radii of different sizes. The plurality of sensors 20 may include first sensors arranged along the first circumference and second sensors arranged along the second circumference. In other words, the plurality of sensors 20 may include first sensors arranged in any one circle from among concentric circle shapes and second sensors arranged in another circle from among the concentric circle shapes.

The first sensors may be arranged at equal intervals (a first sub-angle interval), and the second sensors may be arranged at equal intervals (a second sub-angle interval). A size of a first sub-angle of the first sensors and a size of a second sub-angle of the second sensors may be different from each other. Repeatedly sensing operation S200 of FIG. 2 may be performed by rotating the wafer-like sensing apparatus 1 at every angle equal to a common multiple of the size of the first sub-angle and the size of the second sub-angle.

For brief description, some of the plurality of sensors 20 are described. The other sensors may be applied in the same method with reference to FIG. 5.

Referring to FIG. 5, the plurality of sensors 20 may include first sensors (a sensor 34 to a sensor 49) arranged along a first circumference 20C1 of the virtual circumference 20C. The plurality of sensors 20 may include second sensors (a sensor 50 to a sensor 73) arranged along a second circumference 20C2 of the virtual circumference 20C.

The first sensors (the sensor 34 to the sensor 49) may be spaced apart from one another at every first sub-angle θ11 on the first circumference 20C1. The second sensors (the sensor 50 to the sensor 73) may be spaced apart from one another at every second sub-angle θ12 on the second circumference 20C2. When performing the repeatedly sensing operation S200 of FIG. 2 by rotating the wafer-like sensing apparatus 1 by every first angle θ1, a size of the first angle θ1 may be a common multiple of a size of the first sub-angle θ11 and a size of the second sub-angle θ12. In an embodiment, the size of the first angle θ1 may be the least common multiple of the size of the first sub-angle θ11 and the size of the second sub-angle θ12. The size of the first angle θ1 may be an integer multiple of the size of the first sub-angle θ11 and simultaneously an integer multiple of the size of the second sub-angle θ12. As described above, all data obtained through sensing by the plurality of sensors 20 at every angle may be used by determining the first angle θ1 by considering the arrangement of the plurality of sensors 20.

In the repeatedly sensing operation S200, n different sensors from among a plurality of sensors may each sense the physical quantity at the same measurement point. Here, n may be a value obtained by dividing 360 by the size of the first angle θ1. In FIG. 5, the first sub-angle θ11 may be 22.5°, the second sub-angle θ12 may be 15°, and the first angle θ1 may be 45°. Here, eight sensors may each sense the physical quantity at the same measurement point.

In detail, as illustrated in FIG. 5, when the wafer-like sensing apparatus 1 is rotated counterclockwise at every angle of 45° and loaded, a physical quantity at a location at which the sensor 71 is located may be sensed by the sensor 68 after one rotation, may be sensed by the sensor 65 after two rotations, may be sensed by the sensor 62 after three rotations, may be sensed by the sensor 59 after four rotations, may be sensed by the sensor 56 after five rotations, may be sensed by the sensor 53 after six rotations, may be sensed by the sensor 50 after seven rotations, and may be sensed by the sensor 71 after eight rotations.

Similarly, a physical quantity at a location at which the sensor 72 is located may be sensed by the sensor 69 after one rotation, may be sensed by the sensor 66 after two rotations, may be sensed by the sensor 63 after three rotations, may be sensed by the sensor 60 after four rotations, may be sensed by the sensor 57 after five rotations, may be sensed by the sensor 54 after six rotations, may be sensed by the sensor 51 after seven rotations, and may be sensed by the sensor 72 after eight rotations.

Similarly, a physical quantity at a location at which the sensor 22 of FIG. 5 is located may be sensed by the sensor 20 after one rotation, may be sensed by the sensor 18 after two rotations, may be sensed by the sensor 32 after three rotations, may be sensed by the sensor 30 after four rotations, may be sensed by the sensor 28 after five rotations, may be sensed by the sensor 26 after six rotations, may be sensed by the sensor 24 after seven rotations, and may be sensed by the sensor 22 after eight rotations.

In the same method, from among the plurality of sensors 20, n sensors located on the same virtual circumference 20C may repeatedly sense the physical quantity at the same measurement point.

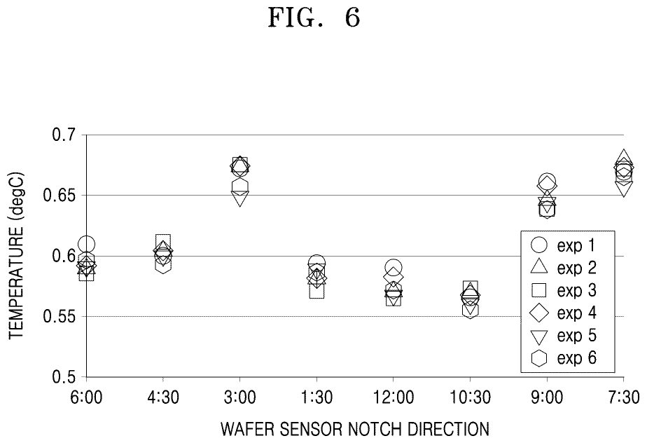

FIG. 6 is a graph obtained through the repeatedly sensing operation S200 of FIG. 2 included in a method of correcting an error of a wafer-like sensing apparatus, according to an embodiment. FIG. 6 illustrates experimental data obtained by performing six sets (a total of 48 evaluations) of conditions for rotating and loading the wafer-like sensing apparatus 1 eight times at 45° intervals in the example of FIG. 5. In FIG. 6, an x-axis represents an angle at which the wafer-like sensing apparatus 1 is rotated and loaded, and a y-axis represents a deviation of a sensed temperature value.

Referring to FIG. 6, with respect to data of six sets exp1, exp2, exp3, exp4, exp5, and exp6, a difference in data at every loading angle (data difference occurring due to unique errors of the plurality of sensors 20) within one set may be greater than a difference in data between respective sets. When the unique errors of the plurality of sensors 20 (refer to FIG. 5) are obtained and corrected according to an embodiment, as shown in FIG. 6, a great data difference at every loading angle may be reduced. In other words, confidence of a measurement value of the wafer-like sensing apparatus 1 (refer to FIG. 5) may be improved.

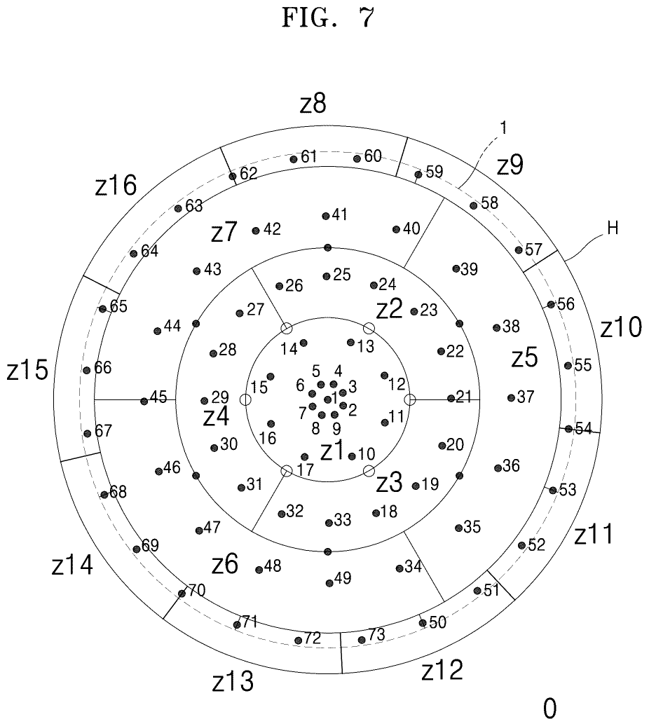

FIG. 7 is a plan view illustrating a schematic arrangement structure of a wafer-like sensing apparatus 1 and a heater H used in a method of correcting an error of a wafer-like sensing apparatus, according to an embodiment.

FIG. 7 illustrates an example arrangement of a multi-zone heater H having 16 zones Z1 to Z16 and a wafer-like sensing apparatus 1 that senses a temperature of a measurement point heated by the heater H. For example, in the case of a second zone Z2, a sensor 22 to a sensor 26 of the wafer-like sensing apparatus 1 may sense a temperature corresponding to the second zone Z2. When the wafer-like sensing apparatus 1 is rotated and loaded at 45° clockwise on the basis of the arrangement of FIG. 7, a sensor 24 to a sensor 28 may sense the temperature corresponding to the second zone Z2.

TABLE 1

| | CCW 225 | CCW 180 |
|---|---|---|
| Default Range | 0.105° C. | 0.155° C. |
| Calculated Sensor Error | 0.083° C. | 0.129° C. |

Table 1 shows result data obtained by measuring the temperature by loading the wafer-like sensing apparatus 1 on the multi-zone heater H as in the example of FIG. 7. In Table 1, CCW 225 refers to a case where a loading angle of the wafer-like sensing apparatus 1 is 225°, and CCW 180 refers to a case where the loading angle of the wafer-like sensing apparatus 1 is 180°. In Table 1, the default range may refer to a default range of a measurement value when measuring by loading the wafer-like sensing apparatus 1 at a corresponding angle, and the calculated sensor error may refer to a default range occurring due to unique errors of a plurality of sensors calculated according to an embodiment described above. In an experiment, the wafer-like sensing apparatus 1 may rotate at every 45° of the loading angle and perform a measurement, and from among the measurements, CCW 225 at which a default error is minimum and CCW 180 at which the default error is maximum are shown as examples in Table 1.

Referring to Table 1, when performing measurement by intactly using the wafer-like sensing apparatus 1, the wafer-like sensing apparatus 1 may have a default error of about 0.105° C. to 0.155° C. However, according to an embodiment, when unique errors of a plurality of sensors are calculated and applied, measurement accuracy of a sensor may be improved up to a range of 0.022° C. to 0.026° C.

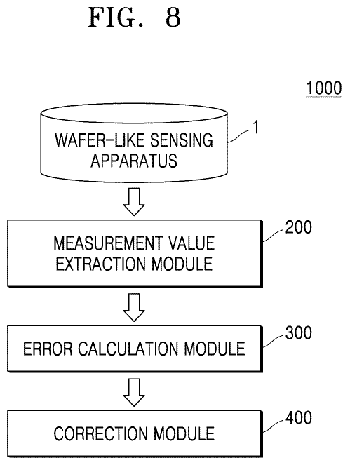

FIG. 8 is a flowchart illustrating an error correction system for performing a method of correcting an error of a wafer-like sensing apparatus, according to an embodiment.

In an embodiment, an error correction system 1000 may include a wafer-like sensing apparatus 1, a measurement value extraction module 200, an error calculation module 300, and a correction module 400.

The term “module” used herein may refer to a functional and structural combination of hardware for performing embodiments of the inventive concept and software for running the hardware. For example, the term “module” may refer to a logical unit of certain code and hardware resources for executing the certain code and does not refer to physically connected code or a type of hardware.

The wafer-like sensing apparatus 1 may include the plurality of sensors 20 (refer to FIG. 5) and may sense physical quantities of various process conditions by using the plurality of sensors 20 (refer to FIG. 5). The wafer-like sensing apparatus 1 may perform repeatedly sensing operation S200 described above with reference to FIGS. 1 to 7. The wafer-like sensing apparatus 1 may be rotated and loaded at every first angle to repeatedly sense a physical quantity at the same measurement point. In an embodiment, the wafer-like sensing apparatus 1 may repeatedly sense one or more physical quantities, such as at least one of temperature, humidity, a distribution of plasma, a density of plasma, a magnetic field, and/or static electricity.

The measurement value extraction module 200 may extract a plurality of measurement values measured respectively by the plurality of sensors through repeated sensing of the wafer-like sensing apparatus 1. The plurality of measurement values may refer to values measured by different sensors at the same measurement point.

The error calculation module 300 may receive the plurality of measurement values extracted by the measurement value extraction module 200 and calculate unique errors of the plurality of sensors 20 or one or more of the plurality of sensors 20. In detail, the error calculation module 300 may calculate a representative value from the plurality of measurement values extracted by the measurement value extraction module 200 and calculate the unique errors of the plurality of sensors 20 by using the calculated representative value. The error calculation module 300 may calculate the unique errors of the plurality of sensors 20 by determining that the calculated representative value is the same as a true value. The error calculation module 300 may calculate the unique errors of the plurality of sensors by determining that each of the plurality of measurement values is the same as a value obtained by adding a unique error of each of the plurality of sensors 20 to the true value.

In an embodiment, the error calculation module 300 may calculate the unique errors of the plurality of sensors 20 by determining that the plurality of measurement values follow a Gaussian distribution. The error calculation module 300 may calculate the unique errors of the plurality of sensors 20 by determining that an average value of the plurality of measurement values is the same as the true value. In other words, the error calculation module 300 may calculate the average value of the plurality of measurement values as the representative value. The embodiments are not limited thereto, and the error calculation module 300 may calculate the representative value by using the plurality of measurement values in various methods as described above.

The correction module 400 may correct an error of the wafer-like sensing apparatus 1 by using the unique errors of the plurality of sensors 20 calculated by the error calculation module 300. The correction module 400 may perform a process of subtracting the unique errors of the plurality of sensors 20 from a result value obtained by using the plurality of sensors 20 of the wafer-like sensing apparatus 1. For example, when the plurality of sensors 20 sense the temperature, the error of the wafer-like sensing apparatus 1 may be corrected through a process of subtracting the unique error of each of the plurality of sensors 20 from a temperature value obtained by using the plurality of sensors 20. Each of the measurement value extraction module 200, the error calculation module 300, and the correction module 400 may be provided within the wafer-like sensing apparatus 1 or may be provided as a separate module connected to the wafer-like sensing apparatus 1.

While the inventive concept has been particularly shown and described with reference to embodiments thereof, it will be understood that various changes in form and details may be made therein without departing from the spirit and scope of the following claims.

What is claimed is:

1. A method of correcting an error of a wafer-like sensing apparatus, the method comprising:
repeatedly sensing a physical quantity at a same measurement point by rotating the wafer-like sensing apparatus having a plurality of sensors arranged along a virtual circumference;
calculating a representative value from a plurality of measurement values extracted through the repeated sensing and calculating a unique error of each of the plurality of sensors by using the representative value; and
correcting the error of the wafer-like sensing apparatus by using the unique error of each of the plurality of sensors.

2. The method of claim 1, wherein the repeatedly sensing comprises rotating the wafer-like sensing apparatus incrementally with each increment corresponding to a first angle of rotation.

3. The method of claim 2, wherein adjacent ones of the plurality of sensors are spaced apart from one another at increments corresponding to the first angle along the virtual circumference.

4. The method of claim 2, wherein the repeatedly sensing comprises sensing the physical quantity at the same measurement point by n different sensors from among the plurality of sensors,
wherein n is a number obtained by dividing 360 by a size of the first angle.

5. The method of claim 2, wherein the plurality of sensors comprises first sensors arranged such that adjacent ones of the first sensors are spaced apart from one another at a first sub-angle along a first circumference of the virtual circumference and second sensors arranged such that adjacent ones of the second sensors are spaced apart from one another at a second sub-angle less than the first sub-angle along a second circumference having a same center point as the first circumference and having a different radius from the first circumference, from among the virtual circumference, and a size of the first angle is a common multiple of a size of the first sub-angle and a size of the second sub-angle.

6. The method of claim 5, wherein the repeatedly sensing comprises repeatedly sensing the physical quantity at the same measurement point eight times at the first angle of 45°.

7. The method of claim 1, wherein the calculating of the unique error of each of the plurality of sensors comprises calculating the unique error of each of the plurality of sensors by determining that the representative value calculated through the repeated sensing is equal to a true value of the physical quantity at the measurement point.

8. The method of claim 7, wherein the representative value is calculated by using an average of at least some of the plurality of measurement values or a root mean square error of the plurality of measurement values.

9. The method of claim 1, wherein the repeatedly sensing comprises sensing temperature, humidity, a distribution of plasma, a density of the plasma, a magnetic field, or static electricity.

10. The method of claim 1, wherein the correcting of the error of the wafer-like sensing apparatus by using the unique error of each of the plurality of sensors comprises:
obtaining, by each of the plurality of sensors, a result value by sensing temperature, humidity, distribution of plasma, density of the plasma, magnetic field, or static electricity; and
subtracting the unique error of each of the plurality of sensors from the plurality of result values, respectively.

11. A method of correcting an error of a wafer-like sensing apparatus, the method comprising:
calibrating a plurality of sensors included in the wafer-like sensing apparatus;
repeatedly sensing a physical quantity at a same measurement point by using n sensors from among the plurality of sensors by rotating the wafer-like sensing apparatus clockwise or counterclockwise incrementally with each increment corresponding to a first angle; and
calculating a calibration error of each of the n sensors by using a plurality of measurement values of the n sensors extracted through the repeated sensing,
wherein n is a natural number of 2 or more.

12. The method of claim 11, wherein the wafer-like sensing apparatus comprises a wafer-shaped substrate and the plurality of sensors are attached to the substrate, and the plurality of sensors are arranged in concentric circle shapes having a center point of the substrate as a center.

13. The method of claim 12, wherein the plurality of sensors comprise first sensors arranged such that adjacent ones of the first sensors are spaced apart from each other at a first sub-angle in a first circle from among the concentric circle shapes and second sensors arranged such that adjacent ones of the second sensors are spaced apart from each other at a second sub-angle less than the first sub-angle in a second circle from among the concentric circle shapes, and a size of the first angle is an integer multiple of a size of the first sub-angle and an integer multiple of a size of the second sub-angle.

14. The method of claim 12, wherein the n sensors are each located at a same distance from the center of the substrate.

15. The method of claim 14, wherein the n sensors are arranged such that adjacent ones of the n sensors are spaced apart from each other at the first angle with respect to the center point of the substrate.

16. The method of claim 11, wherein the calculating of the calibration error of each of the n sensors comprises calculating the calibration error of each of the n sensors by determining each of the plurality of measurement values as a value obtained by adding the calibration error of each of the n sensors to a true value of the physical quantity at the measurement point.

17. The method of claim 11, wherein the wafer-like sensing apparatus is an apparatus configured to sense temperature, humidity, a distribution of plasma, a density of the plasma, a magnetic field, or static electricity.

18. A method of correcting an error of a wafer-like sensing apparatus, the method comprising:
the wafer-like sensing apparatus, which comprises a substrate and a plurality of sensors arranged such that adjacent ones of the plurality of sensors are spaced apart at a first angle along a virtual circumference having a center of the substrate as a center point, rotating at increments corresponding to the first angle to repeatedly sense temperature, humidity, a distribution of plasma, a density of the plasma, a magnetic field, or static electricity of a same measurement point;
by a measurement value extraction module, extracting a plurality of measurement values measured respectively by the plurality of sensors through the repeated sensing;
by an error calculation module, receiving the plurality of measurement values from the measurement value extraction module and calculating unique errors of the plurality of sensors; and
by a correction module, correcting the error of the wafer-like sensing device by using the unique errors of the plurality of sensors.

19. The method of claim 18, wherein the error calculation module is configured to calculate the unique errors of the plurality of sensors by determining that the plurality of received measurement values follow a Gaussian distribution having a true value of the measurement point as a center.

20. The method of claim 18, wherein the correction module is configured to correct the error of the wafer-like sensing apparatus by subtracting the unique error of each of the plurality of sensors from a plurality of result values obtained by using the plurality of sensors, respectively.
